(19) United States
(12) Patent Application Publication
(10) Pub. No.: US 2024/0381730 A1
(43) Pub. Date: Nov. 14, 2024

(54) DISPLAY APPARATUS

(71) Applicant: LG DISPLAY CO., LTD., Seoul (KR)

(72) Inventors: Pu-Reum KIM, Paju-si (KR); Ho-Jin KIM, Paju-si (KR); Jin-Hyeon KIM, Paju-si (KR)

(73) Assignee: LG DISPLAY CO., LTD., Seoul (KR)

(21) Appl. No.: 18/657,950

(22) Filed: May 8, 2024

(30) Foreign Application Priority Data
May 9, 2023 (KR) 10-2023-0059798

(51) Int. Cl. H10K 59/35; G02B 27/01; H10K 59/80

(52) U.S. Cl. CPC H10K 59/353; G02B 27/0172; H10K 59/878

(57) ABSTRACT

A display apparatus includes a substrate including a first sub-pixel and a second sub-pixel disposed adjacent to each other; a first electrode disposed in each of the first sub-pixel and the second sub-pixel on the substrate; a first light emitting layer on the first electrode in the first sub-pixel and a second light emitting layer on the first electrode in the second sub-pixel; a first trench formed between the first electrode of the first sub-pixel and the first electrode of the second sub-pixel; and a second trench formed between the first electrode of the first sub-pixel and the first trench, wherein the first light emitting layer and the second light emitting layer are disposed over the first trench.

### CROSS-REFERENCE TO RELATED DISCLOSURE

This disclosure claims the priority of Korea Patent Disclosure No. 10-2023-0059798, filed on May 9, 2023, which is hereby incorporated by reference in its entirety.

### BACKGROUND

### Field of the Disclosure

This disclosure relates to a high-resolution light emitting display apparatus with improved image quality.

### Description of the Background

Display apparatus used in TVs, monitors, smartphones, laptops, and head-mounted displays has various method and shape.

Among these display apparatus, a light emitting display apparatus (LED) has a structure in which a light emitting layer is formed between an anode electrode and a cathode electrode, and displays an image by emitting light due to an electric field between the two electrodes.

The light emitting layer may be made of an organic material or inorganic material that generates excitons by combining electrons and holes, and emits light when the generated excitons fall from the excited state to the ground state.

The light emitting layer has different colors for each sub-pixel. For example, it may be configured to emit red, green, and blue light, or it may be configured to emit light of the same color, for example, white, for each sub-pixel.

When the light emitting layer emits light of different colors for each sub-pixel, a different light emitting layer must be deposited for each sub-pixel using a mask. If the mask is not precisely aligned or the gap between the mask and the substrate is large, it becomes difficult to precisely deposit the light emitting layer for each sub-pixel.

In the case of the organic light emitting display apparatus in which the spacing between sub-pixels is narrow to achieve high resolution, non-corresponding sub-pixels may emit light due to leakage current flowing laterally. This problem is further aggravated in the case of head mounted display that displays virtual reality (VR) or augmented reality by focusing on a short distance in front of the user's eyes.

In the display apparatus that emits different colors for each sub-pixel, the light emitting layer must be deposited for each sub-pixel using a fine metal mask (FMM). However, when the light emitting layer is deposited by contacting the fine metal mask with the display apparatus, the display apparatus may be damaged. Therefore, to prevent damage to the display apparatus due to the fine metal mask, the fine metal mask must be fixed at regular intervals in the display apparatus.

Due to the constant gap between the fine metal mask and the display apparatus, the light emitting layer material is deposited over an area larger than the intended area. Accordingly, a shadow defect that the light emitting layer material is deposited on the sub-pixel adjacent to the target sub-pixel may occur. Due to the shadow defects, multiple light emitting layers may be deposited in the area between sub-pixels, and mixed colors may be emitted from the overlapped light emitting layers, causing a decrease in display quality.

Further, when the spacing between sub-pixels is narrowed to achieve high resolution, unintended light emission may occur due to leakage current generated from adjacent sub-pixels, and thus display quality may further deteriorate.

### SUMMARY

Accordingly, the present disclosure is directed to a display apparatus that substantially obviates one or more of problems due to limitations and disadvantages described above.

More specifically, the present disclosure is to provide a display apparatus that may reduce display quality degradation due to shadow defects by forming a first trench and a first fence.

The present disclosure is also to provide the display apparatus that may prevent leakage current due to driving of a sub-pixel from being applied to the adjacent sub-pixel by forming a second trench and a second fence.

Additional features and advantages of the disclosure will be set forth in the description which follows and in part will be apparent from the description, or may be learned by practice of the disclosure. Other advantages of the present disclosure will be realized and attained by the structure particularly pointed out in the written description and claims hereof as well as the appended drawings.

To achieve these and other advantages and in accordance with the present disclosure, as embodied and broadly described, a display apparatus includes a substrate including a first sub-pixel and a second sub-pixel disposed adjacent to each other; a first electrode disposed in each of the first sub-pixel and the second sub-pixel on the substrate; a first light emitting layer on the first electrode in the first sub-pixel and a second light emitting layer on the first electrode in the second sub-pixel; a first trench formed between the first electrode of the first sub-pixel and the first electrode of the second sub-pixel; and a second trench formed between the first electrode of the first sub-pixel and the first trench, wherein the first light emitting layer and the second light emitting layer are disposed over the first trench.

In another aspect of the present disclosure, a head mount display includes a substrate including a first sub-pixel and a second sub-pixel disposed adjacent to each other; a first electrode disposed in each of the first sub-pixel and the second sub-pixel on the substrate; a first light emitting layer on the first electrode in the first sub-pixel and a second light emitting layer on the first electrode in the second sub-pixel; a first trench formed between the first electrode of the first sub-pixel and the first electrode of the second sub-pixel; and a second trench formed between the first electrode of the first sub-pixel and the first trench, wherein the first light emitting layer and the second light emitting layer are disposed over the first trench; a lens array space apart from the display apparatus; and a storage case receiving the display apparatus and the lens array.

It is to be understood that both the foregoing general description and the following detailed description are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this disclosure, illustrate aspects of the disclosure and together with the description serve to explain various principles.

In the drawings:

FIG. 1 is a cross-sectional view of a display apparatus according to an aspect of the present disclosure;

FIG. 2 is a cross-sectional view showing a stacked structure of a light emitting unit according to the aspect of the present disclosure;

FIG. 3 is an enlarged cross-sectional view of area A of FIG. 1;

FIG. 4 is a plan view of the display apparatus according to the aspect of the present disclosure;

FIG. 5 is a plan view of the display apparatus according to another aspect of the present disclosure;

FIGS. 6 to 8 are views showing a head mounted display according to the present disclosure.

### DETAILED DESCRIPTION

Advantages and features of the present disclosure and methods for achieving them will be made clear from aspects described in detail below with reference to the accompanying drawings. The present disclosure may, however, be implemented in many different forms and should not be construed as being limited to the aspects set forth herein, and the aspects are provided such that this disclosure will be thorough and complete and will fully convey the scope of the present disclosure to those skilled in the art to which the present disclosure pertains, and the present disclosure is defined only by the scope of the appended claims.

Shapes, sizes, ratios, angles, numbers, and the like disclosed in the drawings for describing the aspects of the present disclosure are illustrative, and thus the present disclosure is not limited to the illustrated matters. The same reference numerals refer to the same components throughout this disclosure. Further, in the following description of the present disclosure, when a detailed description of a known related art is determined to unnecessarily obscure the gist of the present disclosure, the detailed description thereof will be omitted herein. When terms such as “including,” “having,” “consisting of,” and the like mentioned in this disclosure are used, other parts may be added unless the term “only” is used herein. When a component is expressed as being singular, being plural is included unless otherwise specified.

In analyzing a component, an error range is interpreted as being included even when there is no explicit description.

In describing a positional relationship, for example, when a positional relationship of two parts is described as being “on,” “above,” “below,” “next to,” or the like, unless “immediately” or “directly” is not used, one or more other parts may be located between the two parts.

In describing a temporal relationship, for example, when a temporal predecessor relationship is described as being “after,” “subsequent,” “next to,” “prior to,” or the like, unless “immediately” or “directly” is not used, cases that are not continuous may also be included.

Although the terms first, second, and the like are used to describe various components, these components are not substantially limited by these terms. These terms are used only to distinguish one component from another component. Therefore, a first component described below may substantially be a second component within the technical spirit of the present disclosure.

Like reference numerals refer to like elements throughout the disclosure.

The size and thickness of each component shown in the drawings are shown for convenience of explanation, and the present disclosure is not necessarily limited to the size and thickness of the components shown.

Each feature of the various aspects of the present disclosure may be partially or fully combined or combined with each other, and as may be fully understood by those skilled in the art, various technical interconnections and operations are possible, and each aspect may be implemented independently of each other. It may be possible to conduct them together due to a related relationship.

The display apparatus of this disclosure may be applied to an organic light emitting display apparatus, but is not limited thereto, and may be applied to a variety of display apparatus.

Hereinafter, the display apparatus according to an aspect of the present disclosure will be described in detail with reference to the accompanying drawings.

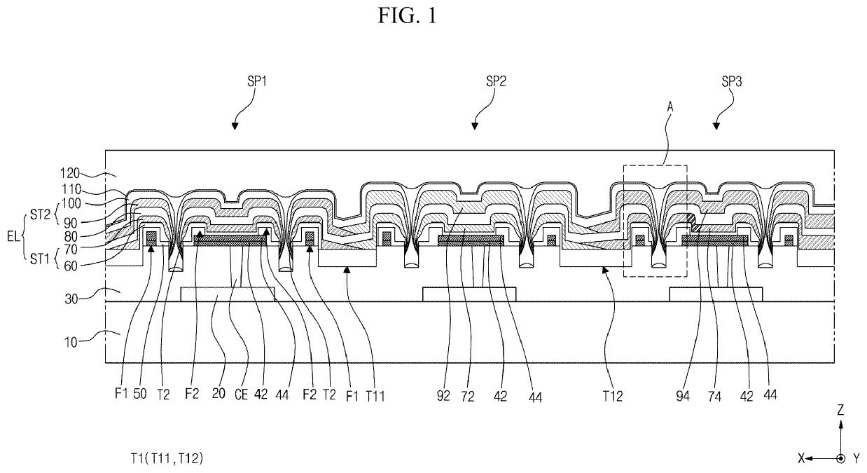

FIG. 1 is a cross sectional view showing a cross section of the display apparatus according to the aspect of the present disclosure.

Referring to FIG. 1, the display apparatus 1 according to the present disclosure includes a substrate 10, a thin film transistor 20, a first insulating layer 30, a reflective layer 42, a first electrode 44, a second insulating layer, a first fence F1, a second fence F2, a light emitting portion EL, a second electrode 110, and an encapsulation layer 120.

The substrate 10 may be made of glass or plastic, but is not limited to this and may be made of a semiconductor material such as a silicon wafer.

A head mounted display that displays virtual reality (VR) or augmented reality by focusing on the distance close to the user's eyes uses the silicon wafer as the substrate 10 to realize high resolution. Further, since the thin film transistor 20, the connection electrode CE, and the first electrode 44 are formed using a semiconductor process, the gap between the sub-pixels SP1, SP2, and SP3 may be minimized.

A first sub-pixel SP1, a second sub-pixel SP2, and a third sub-pixel SP3 arranged adjacently may be formed on the substrate 10. The second sub-pixel SP2 may be placed adjacent to the side of the first sub-pixel SP1, and the third sub-pixel SP3 may be placed adjacent to the side of the second sub-pixel SP2.

The first sub-pixel SP1 may emit blue (B) light, the second sub-pixel SP2 may emit green (G) light, and the third sub-pixel SP3 may emit red (R) light. The color and arrangement of the sub-pixels SP1, SP2, and SP3 are not limited to this. The color, arrangement order, and arrangement shape of the sub-pixels SP1, SP2, and SP3 may be changed in various ways.

The display apparatus 1 according to the aspect of the present disclosure may be of a top emission type in which the emitted light is output upward. At this time, not only transparent materials but also opaque materials may be used as the material for the substrate 10.

Various circuit elements including a thin film transistor 20, a capacitor, a signal lines, etc. may be disposed in each of the sub-pixels SP1, SP2, and SP3 on the substrate 10. The signal line may include a gate line, a data line, a power line, and a reference line, and the thin film transistor 20 may include one or more of a switching thin film transistor, a driving thin film transistor, and a sensing thin film transistor.

The switching thin film transistor is switched according to the gate signal supplied to the gate line and then supplies the data voltage supplied from the data line to the driving thin film transistor.

The driving thin film transistor is switched according to the data voltage supplied from the switching thin film transistor to generate a driving current from the power supplied from the power line and then supplies the generated driving current to the first electrode 44.

The sensing thin film transistor senses the threshold voltage deviation of the driving thin film transistor, which causes deterioration of image quality. The sensing thin film transistor supplies current from the driving thin film transistor to the reference line in response to a sensing control signal supplied from the gate line or a separate sensing line.

The capacitor is respectively connected to the gate terminal and source terminal of the driving thin film transistor to maintain the data voltage supplied to the driving thin film transistor for one frame.

The thin film transistor 20 may be formed in various structures, such as a bottom gate structure and a top gate structure.

A first insulating layer 30 is disposed on circuit elements such as the thin film transistor 20 to protect the circuit elements.

The first insulating layer 30 may be formed of an inorganic material such as silicon nitride (SiNx), silicon oxy nitride (SiON), silicon oxide (SiOx), titanium oxide (TiOx), and aluminum oxide (AlOx). The first insulating layer 30 is not limited thereto \ and may be formed of an organic material.

A planarization layer is formed on the first insulating layer 30 to eliminate steps caused by circuit elements.

The first electrode 44 is formed on the first insulating layer 30 or the planarization layer to supply the driving signal to the light emitting unit EL. The first electrode 44 may be disposed in the first sub-pixel SP1, the second sub-pixel SP2, and the third sub-pixel SP3 on the first insulating layer 30, respectively.

The second electrode 110 is formed on the light emitting unit EL, so that a common voltage or common current may be applied to the light emitting unit EL. The second electrode 110 may be the cathode electrode.

An encapsulation layer 120 is formed over the second electrode 110 to prevent external moisture from penetrating into the light emitting unit EL. The encapsulation layer 120 may be made of the inorganic insulating material or may be made of the structure in which the inorganic insulating materials and the organic insulating materials are alternately deposited, but is not limited thereto.

A color filter layer may be formed on the encapsulation layer 120. The color filter layer may be formed to correspond to each of the sub-pixels SP1, SP2, and SP3. The color filter layer may include blue filter, green filter, and red color filters.

The thin film transistor 20 is connected to the first electrode 44 to supply the driving signal such as the driving current to the first electrode 44. The thin film transistor 20 and the first electrode 44 may be connected through a connection electrode CE.

A reflective layer 42 may be formed under the first electrode 44. The reflective layer 42 may be placed in contact with the first electrode 44 to reduce the resistance of the first electrode 44.

The reflective layer 42 may reflect light. The light emitted from the light emitting unit EL and propagating downward is reflected upward by the reflection layer 42, thereby improving light efficiency and realizing a micro cavity effect. The reflective layer 42 may be disposed to be in contact with the first insulating layer 30.

When the reflective layer 42 is formed under the first electrode 44, the connecting electrode CE is connected to the reflective layer 42 to apply the driving signal of the thin film transistor 20 to the first electrode 44 through the connecting electrode CE and the reflective layer 42.

The connection electrode CE may be formed by forming a contact hole in the first insulating layer 30 to expose the source terminal or drain terminal of the thin film transistor 20 and then injecting the metal material into the contact hole.

The first electrode 44 and/or the reflective layer 42 may be formed in a pattern to correspond to each of the sub-pixels SP1, SP2, and SP3. The first electrode 44 and/or the reflective layer 42 may be the anode electrode.

Since the display apparatus according to the aspect of the present disclosure is a top emission type, the first electrode 44 may be formed to reflect light emitted from the light emitting unit EL upward.

The first electrode 44 is made as a transparent electrode or a semi-transparent electrode, so that light emitted from the light emitting unit EL is reflected by the reflective layer 42 upward. The reflective layer 42 may be arranged in each sub-pixel SP1, SP2, and SP3 to implement a micro cavity effect.

The micro cavity effect occurs when the distance between the reflective layer 42 and the second electrode 110 is an integer multiple of the half-wavelength (2) of the light emitted from each sub-pixel SP1, SP2, and SP3, thereby causing constructive interference and amplifying the light. When the reflection and re-reflection process of light is repeated between the reflection layer 42 and the second electrode 110, the degree to which light is amplified continues to increase, thereby improving the efficiency of external extraction of light.

In each sub-pixel SP1, SP2, and SP3, the thickness of the light emitting unit EL may be varied to have an optimal micro cavity effect. Since the wavelength of light generated from each sub-pixel SP1, SP2, and SP3 has a different wavelength for each color, the thickness of the light emitting unit EL may be formed differently to match the wavelength of light generated from each color. The distance between the reflective layer 42 and the second electrode 110 may be controlled by adjusting the thickness of the light emitting unit EL. By controlling the distance between the reflective layer 42 and the second electrode 110 differently for each sub-pixel SP1, SP2, and SP3, the optimal micro cavity effect may be realized to correspond to each wavelength.

For example, in the case of the first sub-pixel SP1, the distance from the reflective layer 42 to the second electrode 110 may be shorter than that of the second sub-pixel SP2 and the third sub-pixel SP3. In the case of the second sub-pixel SP2, the distance from the reflective layer 42 to the second electrode 110 may be shorter than that of the third sub-pixel SP3.

The first electrode 44 may be formed of the transparent electrode made of TiN or ITO, and the reflective layer 42 may be formed of the reflective electrode made of aluminum (Al) or silver (Ag).

The first electrode 44 and the reflective layer 42 may be formed by entirely depositing materials of the first electrode 44 and the reflective layer 42 on the substrate 10 and then performing a single patterning process.

A first fence F1 may be formed in each area where the sub-pixels SP1, SP2, and SP3 are located to prevent leakage current between adjacent pixels.

The first fence F1 is formed at a height greater than the surrounding area, and the light emitting unit EL deposited on the first fence F1 is disconnected from the sub-pixels SP, SP2, and SP3, thereby reducing display quality due to leakage current.

To form the first fence F1, the first layer and the second layer constituting the first fence F1 may be patterned simultaneously during the patterning process of the first electrode 44 and the reflective layer 42. The second layer of the first fence F1 may be formed of the same material as the reflective layer 42, and the first layer may be formed of the same material as the first electrode 44.

A second insulating layer 50 may be disposed over the first insulating layer 30. The second insulating layer 50 may be disposed in the area surrounding the edge of the first electrode 44. The second insulating layer 50 may be disposed at the end of the first electrode 44 disposed in each of the sub-pixels SP1, SP2, and SP3 to form a second fence F2.

For example, the second insulating layer 50 may be formed over both ends of the first electrode 44 to cover a portion of the top surface and the side surface of the first electrode 44 to form the second fence F2. The second insulating layer 50 is formed to cover a portion of the first insulating layer 30 to prevent the decrease in luminous efficiency caused by current concentration at the end of the first electrode 44. The first electrode 44 exposed and not covered by the second fence F2 may become a light emitting area. The second insulating layer 50 may be made of the inorganic insulating layer, but is not limited thereto.

The second fence F2 is formed by stacking the reflective layer 42, the first electrode 44, and the second insulating layer 50, and may be thicker than adjacent areas and have a high level step.

Since the light emitting unit EL formed on the second fence F2 and the second insulating layer 50 is deposited continuously over the entire area of the display apparatus 1 without interruption, the leakage current may be flow to the adjacent sub-pixel through the light emitting unit EL. Due to the step caused by the second fence F2, the light emitting unit EL may be formed in thin thickness or the disconnection portion may be formed in the light emitting unit EL, so that the leakage current may be blocked to the adjacent sub-pixel by the thin portion or the disconnection portion of the light emitting unit EL.

The first fence F1 may be formed to surround the second fence F2 in the area adjacent to the second fence F2. The first fence F1 may be formed of the material of the reflective layer 42, material of the first electrode 44 material, and the second insulating layer 50 that constitute the second fence F2. The first fence F1 may have the same thickness as the second fence F2.

The first fence F1 may also increase resistance by forming the thin thickness of the light emitting unit EL by the high level step, or make it difficult for leakage current to move by forming disconnection portion in the light emitting unit EL.

To implement high resolution, in case where the gap between the sub-pixels SP1, SP2, and SP3 is narrowed and the first fence F1, the second fence F2, a first trench T1, and a second trench T2 are formed, the space in which the first electrode 44 may be formed becomes narrow, so that the brightness of the light generated from the light emitting unit EL may be lowered.

To increase the brightness of light emitted from the sub-pixels SP1, SP2, and SP3, the light emitting unit EL may be formed of a plurality of stacks.

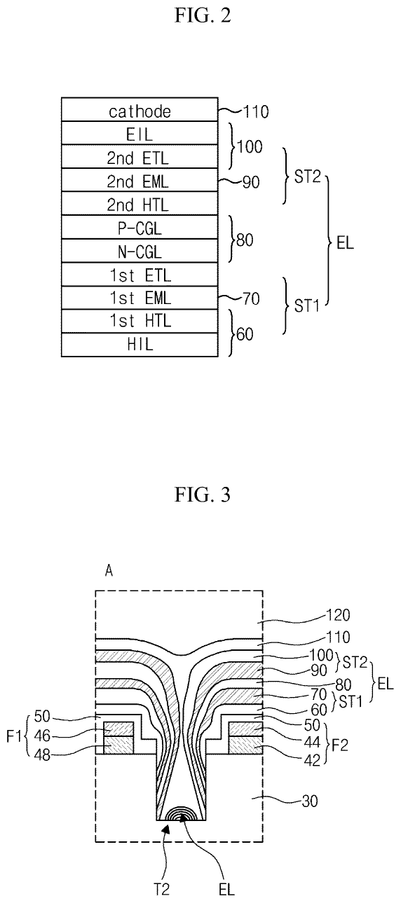

As shown in FIG. 2, for example, the light emitting unit EL may be formed to include a plurality of stacks that emit light of the same color. The light emitting unit EL includes a first stack ST1, a second stack ST2, and a charge generation layer CGL 80 between the first stack ST1 and the second stack ST2.

The first stack ST1 is disposed on the first electrode 44 and may include a first transporting layer 60 and a first emitting layer 1st EML, 70. The first transporting layer 60 may be a hole injecting layer (HIL) and/or a hole transporting layer (HTL).

An electron transporting layer (ETL) and/or an electron injecting layer (EIL) may be further disposed on the first light emitting layer 70.

The second stack ST2 may be disposed between the charge generation layer 80 and the second electrode 110, and includes a first auxiliary emitting layer 2nd EML, 90 and a second transporting layer 100. The second transporting layer 100 may be an electron injecting layer EIL and/or an electron transporting layer ETL.

A hole transporting layer HTL and/or a hole injecting layer HIL may be further disposed under the first auxiliary light emitting layer 90.

The charge generation layer 80 disposed between the first stack ST1 and the second stack ST2 supplies charges to the first stack ST1 and the second stack ST2. The charge generation layer 80 includes an N-type charge generation layer for supplying electrons to the first stack ST1 and a P-type charge generation layer for supplying holes to the second stack ST2. The N-type charge generation layer may include a metal material as a dopant.

In the first sub-pixel SP1, the first auxiliary light emitting layer 90 of the second stack ST2 may be disposed on the first light emitting layer 70 of the first stack ST1. The first light emitting layer 70 and the first auxiliary light emitting layer 90 may emit light of the same color or light of different colors.

In the second sub-pixel SP2, a second light-emitting layer 72 and a second auxiliary light-emitting layer 92 that emit light of a different color than that of the first sub-pixel SP1 may be disposed. In the third sub-pixel SP3, a third light-emitting layer 74 and the second auxiliary light-emitting layer 94 that emit light of a different color from those of the first sub-pixel SP1 and the second sub-pixel SP3 may be disposed.

In the light emitting unit EL, except for the first light emitting layer 70, the second light emitting layer 72, the third light emitting layer 74, the first auxiliary light emitting layer 90, the second auxiliary light emitting layer 92, and the third auxiliary light emitting layer 94, other elements may be arranged continuously in the sub-pixels SP1, SP2, and SP3. The first sub-pixel SP1 may emit blue light, the second sub-pixel SP2 may emit green light, and the third sub-pixel SP3 may emit red light.

The first light emitting layer 70, the second light emitting layer 72, and the third light emitting layer 74 may be disposed on the first electrode 44 in each sub-pixel SP1, SP2, and SP3 to receive charges.

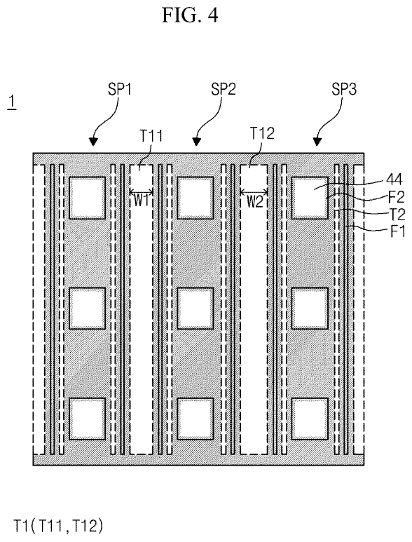

FIG. 3 is the cross sectional view showing a detailed stacked structure of the light emitting unit according to the aspect of the present disclosure.

Referring to FIG. 3, the first stack ST1 includes the hole injecting layer HIL, the first hole transporting layer 1st HTL on the hole injecting layer HIL, the first emitting layer 1st EML, 70 on the first hole transporting layer 1st HTL, and the first electron transporting layer 1st ETL on the first emitting layer 1st EML, 70, but is not limited thereto. The hole injecting layer HIL and the first hole transporting layer 1st HTL may be the first transporting layer 60. The first emitting layer 1st EML, 70 may be made of the emitting layer of yellow-green, red, green, or blue.

The charge generation layer 80 may include the N-type charge generation layer N-CGL on the first stack ST1 and the P-type charge generation layer P-CGL on the N-type charge generation layer N-CGL. The N-type charge generation layer N-CGL may supply electrons to the first stack ST1, and the P-type charge generation layer P-CGL may supply holes to the second stack ST2.

The second stack ST2 includes the second hole transporting layer 2nd HTL on the charge generation layer 80, the first auxiliary light emitting layer 2nd EML, 90 on the second hole transporting layer 2nd HTL, the second electron transporting layer 2nd ETL on the first auxiliary light emitting layer 2nd EML, 90 and the electron injecting layer EIL on the second electron transporting layer 2nd ETL, but not limited thereto.

The second electron transporting layer 2nd ETL and the electron injecting layer EIL may be the second transporting layer 100. The first auxiliary light emitting layer 90 may be made of the light emitting layer of yellow-green, red, green, or blue.

The hole injecting layer HIL and charge generation layer 80 of the first stack ST1 have relatively high electrical conductivity compared to other layers. Therefore, when the hole injecting layer HIL is connected between the sub-pixels SP1, SP2, and SP3 arranged adjacent to each other or the charge generation layer 80 is connected between the sub-pixels SP1, SP2, and SP3 arranged adjacent to each other, the current flows through the hole injecting layer HIL or charge generation layer 720, so that the leakage current may generate between adjacent sub-pixels SP1, SP2, and SP3.

According to the aspect of the present disclosure, the hole injecting layer HIL and/or the charge generation layer 80 are disconnected within the first trench T1 and/or the second trench T2, so that the leakage current between adjacent sub-pixels SP1, SP2, and SP3 may be prevented.

In the case of the RGB type display apparatus that emits different colors for each sub-pixel SP1, SP2, and SP3, the first light emitting layer 70 and the first auxiliary light emitting layer 90 that emit light of the same color are disposed on the first stack ST1 and the second stack ST2, so that the brightness of the light generated from the light emitting unit EL may be increased.

In the first sub-pixel SP1, the first light emitting layer 70 and the first auxiliary light emitting layer 90 may be composed of the blue light emitting layer. In the second sub-pixel SP2, the second light emitting layer 72 and the second auxiliary light emitting layer 92 may be composed of the green light emitting layer. In the third sub-pixel SP3, the third light emitting layer 74 and the third auxiliary light emitting layer 94 may be composed of the red light emitting layer.

In the case of a WRGB type display apparatus that emits the same color for each sub-pixel SP1, SP2, and SP3, the blue light emitting layer may be used as the light emitting layer of each sub-pixel SP1, SP2, and SP3 and a yellow green light emitting layer may be used as the auxiliary light-emitting layer, so that the light from the light emitting layer and the auxiliary light emitting layer may be mixed to generate white light. A color filter is further placed in each sub-pixel SP1, SP2, and SP3, so that each sub-pixel SP1, SP2, and SP3 may display a different color.

Referring to FIG. 1, before forming the light emitting unit EL, the second insulating layer 50 and/or the first insulating layer 30 may be patterned to form the first trench T1 and the second trench T2.

The first trench T1 may be formed in the boundary area between the sub-pixels SP1, SP2, and SP3. For example, the first trench T1 may be formed in each of the boundary area between the first sub-pixel SP1 and the second sub-pixel SP2 and the boundary area between the second sub-pixel SP2 and the third sub-pixel SP3.

The second trench T2 may be formed between the first trench T1 and the first electrode 44 in each of the sub-pixels SP1, SP2, and SP3.

For example, the second trench T2 may be disposed between the first electrode 44 and the first trench T1 of the first sub-pixel SP1.

The first trench T1 may be formed at the boundary point where each sub-pixel SP1, SP2, and SP3 meet, and the second trench T2 may be formed at the region adjacent to the first electrode 44.

For example, the first trench T1 may be disposed between the first electrode 44 of the first sub-pixel SP1 and the first electrode 44 of the second sub-pixel SP2. The second trench T2 may be disposed between the first electrode 44 of the first sub-pixel SP1 and the first trench T1. The first sub-pixel SP1 may be the area including the first electrode 44, a portion of the first trench T1, and the second trench T2.

The first trench T1 and the second trench T2 prevent leakage current and mixed color emission between adjacent sub-pixels SP1, SP2, and SP3. To implement high resolution, in ace where the interval between sub-pixels SP1, SP2, and SP3 is narrow, and when light is emitted from the light emitting unit EL of any one of the sub-pixels SP1, SP2, and SP3, the electric charges of the corresponding light emitting unit EL may move to the light emitting unit EL in adjacent sub-pixels SP1, SP2, and SP3, resulting in leakage current.

In the aspect of the present disclosure, the first trench T1 and the second trench T2 are formed in the boundary area between the sub-pixels SP1, SP2, and SP3, so that the light emitting units between the adjacent sub-pixels SP1, SP2, and SP3 are disconnected from each other and then the leakage current between adjacent sub-pixels SP1, SP2, and SP3 may be prevented.

The first trench T1 is formed to prevent mixed color emission that may occur when the first emitting layer 70 and/or the first auxiliary emitting layer 90 are deposited at the ends of adjacent sub-pixels SP1, SP2, and SP3 by the shadow defect In the boundary area between the sub-pixels SP1, SP2, and SP3, the light emitting unit EL of the adjacent sub-pixels SP1, SP2, and SP3 may overlap, but the color mixed light emission due to the overlapped emitting unit EL may be indirectly prevented by the first trench T1. The first emitting layer 70 and/or the first auxiliary emitting layer 90 disposed on the first electrode 44 may be disposed only on the first trench T1. The first light emitting layer 70 and/or the first auxiliary light emitting layer 90 may be confined to prevent it from escaping the first trench T1. Further, the first light emitting layer 70 and/or the first auxiliary light emitting layer 90 may be formed in a state where a portion is disconnected due to the step in the first trench T1.

The first trench T1 is disposed between the first sub-pixel SP1 and the second sub-pixel SP2. The first emitting layer 70 of the first sub-pixel SP1 and the second emitting layer 72 of the second sub-pixel SP2 may be deposited in the first trench T1.

For convenience of explanation, the first trench disposed between the first sub-pixel SP1 and the second sub-pixel SP2 is indicated as T11, and the first trench disposed between the second sub-pixel SP2 and the third sub-pixel SP3 is indicated as T12.

To effectively prevent mixed color emission in the boundary area of the adjacent sub-pixels SP1, SP2, and SP3, the width of the first trench T1 may be changed depending on the thickness of the light emitting unit EL of the adjacent sub-pixels. The light emitting unit EL includes a plurality of light emitting layers, and the first light emitting layer 70, the second light emitting layer 72, and the third light emitting layer 74 have different thicknesses. The width of the first trench T1 is determined depending on the thickness of the first emitting layer 70, the second emitting layer 72, and the third emitting layer 74.

For example, the light emitting unit EL of the first sub-pixel SP1 has a thinner thickness than the light emitting unit EL of the third sub-pixel SP3, so the first trench T11 between the first sub-pixel SP1 and the second sub-pixel SP2 has a narrower width than the first trench T12 between the third sub-pixel SP3 and the second sub-pixel SP2.

As the amount of light emitting material deposited on the sub-pixels SP1, SP2, and SP3 increases, the width of the first trench T1 is increased, so that the shadow defect that the light emitting unit EL of the corresponding sub-pixel is formed in the adjacent sub-pixel SP1, SP2, and SP3 may be prevented. The width of the first trench T1 may be determined depending on the material of the light emitting unit EL.

The amount of light emitting material deposited in the first sub-pixel SP1 is less than the amount of light emitting material deposited in the third sub-pixel SP3, and the invasion amount of the light emitting material of the first sub-pixel SP1 to the adjacent second and third sub-pixels SP2 and SP3 is decreased. Accordingly, the width of the first trench T11 between the first sub-pixel SP1 and the second sub-pixel SP2 is smaller than the width of the first trench T12 between the third sub-pixel SP3 and the second sub-pixel SP2.

The first trench T1 may be formed by patterning a portion of the first insulating layer 30 and/or the second insulating layer 50. That is, the first trench T1 may be a portion in which a part of the first insulating layer 30 and/or the second insulating layer 50 is removed.

The depth of the first trench T1 may become deeper in proportion to the amount of light emitting unit EL deposited in the adjacent sub-pixels. When the amount of light emitting unit EL deposited in the adjacent sub-pixels is small, the first trench T1 may be formed by patterning only the second insulating layer 50.

The first trench T1 may be formed at a depth that confines the light emitting material deposited in corresponding sub-pixel and prevents it from flowing to the adjacent sub-pixel.

The depth of the first trench T1 may vary depending on the amount of light emitting portion EL deposited in an adjacent sub-pixel. For example, the amount of material of the light emitting unit EL deposited in the first sub-pixel SP1 and the second sub-pixel SP2 is smaller than the amount of material of the light emitting unit EL deposited in the third sub-pixel SP3, the depth of the first trench T11 between the first sub-pixel SP1 and the second sub-pixel SP2 is less than the depth of the first trench T12 between the third sub-pixel SP3 and the second sub-pixel SP2.

The material of the light emitting unit EL that invades adjacent sub-pixels due to shadow defects is confined in the first trench T1, and the width and depth of the first trench T1 may be formed so that the light emitting units EL of adjacent sub-pixels are overlapped only in the first trench T1.

The depth of the first trench T1 may be smaller than the depth of the second trench T2. Since the first trench T1 serves to confine the light emitting unit EL, the first trench T1 may be formed shallower than the second trench T2 that serves to disconnect the light emitting unit EL. That is, the distance from the substrate 10 to the bottom surface of the first trench T1 may be longer than the distance from the substrate 10 to the bottom surface of the second trench T2.

When electrons and holes are applied to the overlapping light emitting portion EL in the first trench T1, mixed colors may be emitted within the first trench T1. Thus, it is possible to prevent leakage current applied to the light emitting unit EL in the first trench T1 by disconnecting the light emitting unit EL connected to the first electrode 44 or increasing the resistance of the light emitting unit EL connected to the first electrode 44. When the hole injecting layer HIL and the charge generation layer 80, which have high electrical conductivity, are disconnected, the leakage current may be effectively prevented.

The first fence F1 is formed in the area between the first electrode 44 and the first trench T1 or the area between the first trench T1 and the second trench T2 so that the light emitting unit EL may be disconnected. The end of the first fence F1 may be aligned with the end of the first trench T1. Due to the high level step between the first fence F1 and the first trench T1, the deposited light emitting unit EL is completely disconnected or formed to the thin thickness, so that at least one of the hole injecting layer HIL and the charge generation layer 80 may be disconnected, thereby preventing leakage current.

The first fence F1 and the first trench T1 may be formed at the same time by forming the second insulating layer 50 and then patterning thereof, and the first fence F1 and the first trench T1 may be aligned by patterning thereof.

The second trench T2 may be disposed between the first trench T1 and the first electrode 42 or between the first fence F1 and the second fence F2. For example, the second trench T2 may be disposed between the first electrode 44 of the first sub-pixel SP1 and the first trench T1.

Similar to the first trench T1, the second trench T2 may be a portion in which a part of the first insulating layer 30 and/or a part of the second insulating layer 50 are removed. Since the light emitting unit EL is disconnected by the second trench T2 or the light emitting unit EL is formed thin within the second trench T2, the leakage current to the adjacent sub-pixels may be prevented. Further, since the length of the light emitting unit EL is increased by the second trench T2, the current path of the leakage current to the adjacent sub-pixels is lengthened, thereby increasing the resistance and then reducing the leakage current.

FIG. 3 is the enlarged cross sectional view of area A of FIG. 1.

Referring to FIG. 3, the light emitting unit EL includes the first stack ST1 for emitting the light of a first color, the second stack ST2 for emitting the light of the same color or a different color from the first color, and the charge generation layer 80 between the first stack ST1 and the second stack ST2.

The first stack ST1 may be formed on the inner side surface of the second trench T2 during and after deposition process. Further, the first stack ST1 may be formed on a portion of the bottom surface of the second trench T2. The first stack ST1 on the inner side surface of the second trench T2 and the first stack ST1 on the bottom surface of the second trench T2 are disconnected from each other. Accordingly, the first stacks ST1 on different inner side surfaces of the second trench T2, for example, on the left and right side surface of the second trench T2, are disconnected from each other. Thus, the charges are not move between the adjacent sub-pixels SP1, SP2, and SP3 through the first stack ST1.

The first stack ST1 includes the first transporting layer 60 and the first light emitting layer 70. The first light emitting layer 70 may be disconnected within the second trench T2 of the first sub-pixel SP1 and may be continuously disposed in other area. The charge generation layer 80 may be formed on the first stack ST1 in the side surfaces of the second trench T2. At this time, the charge generation layers 80 on different side surfaces of the second trench T2, for example, on the left and right side surfaces of the second trench T2, are disconnected from each other. Thus, the charges are not move between the adjacent sub-pixels SP1, SP2, and SP3 through the charge generation layer 80.

Like the first stack ST2, when the second trench T2 has a sufficiently wide width and depth, the second stack ST2 is also disconnected from each other with the second trench T2 in between, so that the charges cannot move between adjacent sub-pixels SP1, SP2, and SP3.

However, if the area where the second trench T2 is formed is insufficient in the display apparatus, the second stack ST2 may be connected between the sub-pixels SP1, SP2, and SP3. In this case, the charges may move between adjacent sub-pixels SP1, SP2, and SP3 through the second stack ST2.

By appropriately adjusting the shape of the second trench T2 and the deposition process of the light emitting unit EL, the second stack ST2 may also be disconnected between the sub-pixels SP1, SP2, and SP3 arranged adjacently with the second trench T2 in between. Only a lower portion of the second stack ST2 adjacent to the charge generation layer 80 may be disconnected between the sub-pixels SP1, SP2, and SP3.

When a part of the second stack ST2 is connected between the sub-pixels SP1, SP2, and SP3, the charges may move to adjacent sub-pixels. However, due to the disconnection of the charge generation layer 80 and the increase in resistance, only the small amount of charge is moved, and as a result, it may not be significantly affected by leakage current.

The second fence F2 may be formed between the second trenches T2, and the first fence F1 may be formed between the first trench T1 and the second trench T2.

Referring to FIG. 3, the first fence F1 may be formed on the left side of the second trench T2. To form the high level step, the first fence F1 includes the first layer 46 made of the same material as the first electrode 44, the second layer 48 made of the same material as the reflective layer 42, and the second insulating layer 50. To adjust the height of the first fence F1, only one of the first layer 46 and the second layer 48 may be formed. For example, the first fence F1 may be formed of the first layer 46 made of the same material as the first electrode 44 and a second insulating layer 50, or the first fence F1 may further include the second layer 48 made of the same material as the reflective layer 42.

The first layer 46 and the second layer 48 of the first fence F1 are covered by the second insulating layer 50, so that the first layer 46 and the second layer 48 are protected.

The second fence F2 may be formed on the right side of the second trench T2. The second fence F2 may be formed of the second insulating layer 50, the reflective layer 42, and the first electrode 44. The second insulating layer 50 is formed on the first electrode 44 to surround the edge of the first electrode 44. The second fence F2 may be disposed at the edge area of the first electrode 44. Accordingly, the second fence F2 may be formed in the structure in which the second insulating layer 50 may cover both ends of the first electrode 44 in each of the sub-pixels SP1, SP2, and SP3.

Specifically, the second fence F2 is formed in the structure in which the second insulating layer 50 covers the portion of the upper surface and side surface of the first electrode 44 and the side surface of the reflective layer 42 at both ends of the first electrode 44. Accordingly, the second fence F2 may include a portion of the end of the first electrode 44 and a portion of the second insulating layer 500 overlapped with the first electrode 44. When the reflective layer 42 is disposed under the first electrode 44, the second fence F2 may further include a portion of the reflective layer 42 overlapped with the first electrode 44.

The ends of the first fence F1 and/or the second fence F2 are aligned with the ends of the second trench T2, so that the light emitting unit EL is disconnected between the first electrode 44 and the second trench T2. Therefore, since the height of the step of the second trench T2 is the sum of the depth of the second trench T2 and the height of the second fence F2, the light emitting unit EL is effectively disconnected or the thickness of the light emitting unit EL is effectively reduced. Since the end of the first fence F1 may be aligned with the end of the second trench T2, the light emitting unit EL may be disconnected or formed thin.

The ends of the first fence F1 and/or the second fence F2 may not be aligned with the ends of the second trench T2. The first fence F1 and/or the second fence F2 may be formed to have the step from the second trench T2. Due to this step, the effect of disconnection and thin thickness of the light emitting portion EL may be reduced, but damage to the first electrode 44 and the reflective layer 42 that may occur in the process of forming the second trench T2 may be reduced.

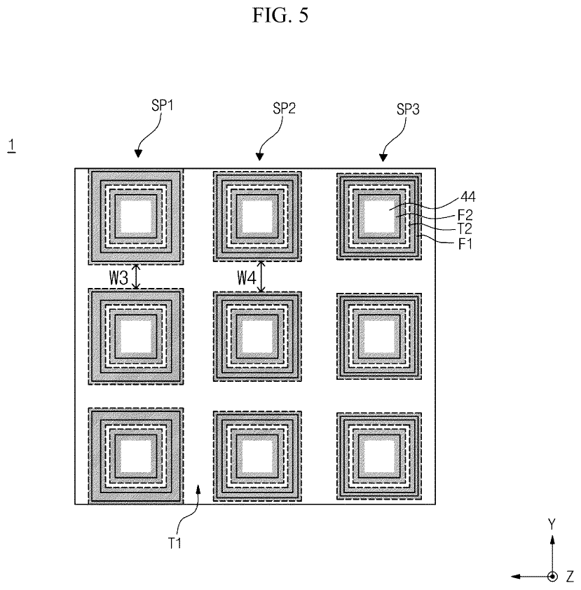

FIG. 4 is a plan view showing the display apparatus according to the aspect of the present disclosure.

Referring to FIG. 4, a plurality of first sub-pixels SP1 for emit the light of the same color may be arranged along the Y direction, which is the first direction, a plurality of second sub-pixels SP2 for emit the light of the same color may be arranged along the first direction, and a plurality of third sub-pixels SP3 for emit the light of the same color may be arranged along the first direction. That is, each of the first sub-pixel SP1, the second sub-pixel SP2, and the third sub-pixel SP3 may each include a plurality of sub-pixels arranged along the first direction.

Further, the first sub-pixel SP1, the second sub-pixel SP2, and the third sub-pixel SP3 may be sequentially arranged along the X-axis direction, which is the second direction.

The first electrode 44 is patterned in each of the sub-pixels SP1, SP2, and SP3, and the second insulating layer 50 is formed in the area except for the first electrode 44, the first trench T1, and the second trench T2.

The first trench T1 and the second trench T2 are extended along the first direction in the boundary area between the first sub-pixel SP1 and the second sub-pixel SP2 and between the second sub-pixel SP2 and the third sub-pixel SP3. The first trench T1) and the second trench T2 may be formed in stripe structure in the whole area of the display apparatus.

The first trench T1 and the second trench T2 cannot be formed in boundary areas between a plurality of first sub-pixels SP1 for emitting the light of the same color, between a plurality of second sub-pixels SP3 for emitting the light of the same color, and between a plurality of third sub-pixels SP3 for emitting light of the same color. The first trench T1 and the second trench T2 may not be formed in the stripe shape extending in the second direction.

Since the charge moves between two adjacent first sub-pixels SP1, between two adjacent second sub-pixels SP2, and between two adjacent third sub-pixels (SP3), the light emission may occur due to leakage current. However, since the charge moves between the sub-pixels SP1, SP2, and SP3 for emitting light of the same color, the reduction in display quality due to leakage current may not be significant.

The width of the first trenches T11 and T12 may dependent upon the thickness of the light emitting unit EL of the adjacent sub-pixel. The width W1 of the first trench T11 between the first sub-pixel SP1 and the second sub-pixel SP2 may be different from the width W2 between the third sub-pixel SP2 and the second sub-pixel SP2.

For example, since the thickness of the light emitting unit EL of the first sub-pixel SP1 is smaller than that of the light emitting unit EL of the third sub-pixel SP3, the width W1 of the first trench T11 between the first sub-pixel SP1 and the second sub-pixel SP2 is smaller than width W2 of the first trench T12 between the third sub-pixel SP3 and the second sub-pixel SP2.

As the amount of light emitting material deposited on the sub-pixels SP1, SP2, and SP3 increases, the width of the first trench T11, T12, and T13 is increased, so that the shadow defect that the light emitting unit EL of the corresponding sub-pixel is formed in the adjacent sub-pixel SP1, SP2, and SP3 may be prevented. That is, the width of the first trench T1 may be determined depending on the material of the light emitting unit EL.

To effectively disconnect the light emitting unit EL and effectively confine the light emitting unit EL within the first trench T1, the first fence F1 may be disposed in the same shape as the first trench T1.

The second fence F2 is arranged to overlap the first electrode 44 and surround the first electrode 44, so that the light emitting unit EL connected to the first electrode 44 may be disconnected.

The second trench T2 may be disposed between the first trench T1 and the first electrode 44. The second trench T2 may be formed in a shape corresponding to the first electrode 44 or may be formed in a shape corresponding to the first trench T1. When the second trench T2 is formed as a stripe shape extending in the first direction, the light emitting unit EL is not disconnected between the sub-pixels SP1, SP2, and SP3 for emitting light of the same color. However, since the charge moves between the sub-pixels SP1, SP2, and SP3 for emitting light of the same color, the reduction in display quality due to leakage current may not be significant.

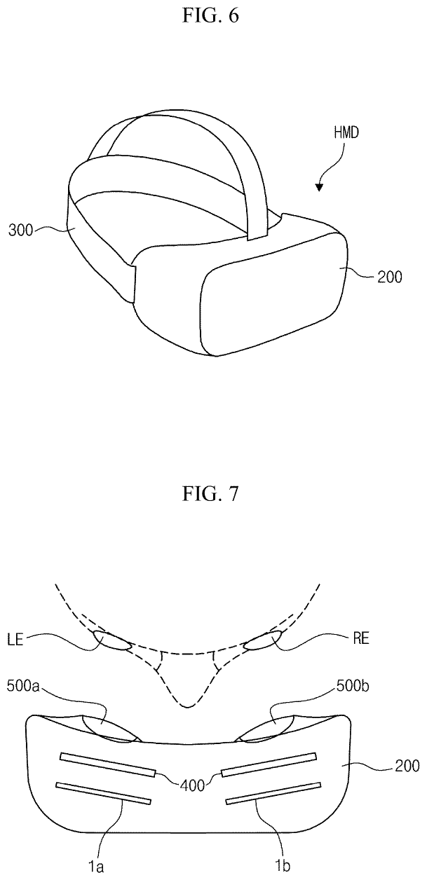

FIG. 5 is a plan view illustrating the display apparatus according to another aspect of the present disclosure.

Referring to FIG. 5, the first trench T1 and the second trench T2 may be further formed in boundary areas between a plurality of first sub-pixels SP1 for emitting the light of the same color, between a plurality of second sub-pixels SP3 for emitting the light of the same color, and between a plurality of third sub-pixels SP3 for emitting light of the same color. That is, the first trench may be further disposed along the second direction, which is the X-axis direction, between the plurality of first sub-pixels SP1 and between the plurality of second sub-pixels SP2.

The first trench T1 extends along the first direction in the boundary area between the sub-pixels SP1, SP2, and SP3 for emitting the light of different colors, and the first trench T1 may extend along the second direction in the boundary area between the sub-pixels SP1, SP1, and SP3 for emitting the light of the same color.

The width W3 between the first sub-pixels SP1 and the width W4 between the second sub-pixels SP2 of the first trench T1 extending in the second direction may be different. For example, since the thickness of the light emitting unit EL of the first sub-pixel SP1 is smaller than that of the second sub-pixel SP2, the width W3 of the first trench T1 between the sub-pixels SP1 may be smaller than the width W4 of the first trench T1 between the second sub-pixels SP2.

As the amount of material of the light emitting unit EL deposited in the sub-pixels SP1, SP2, and SP3 increases, the width of the first trench T1 extending in the second direction may be increased to prevent shadow defects.

Accordingly, the first trench T1 may have different widths in all boundary areas between the sub-pixels SP2, SP2, and SP3, and the first trench T1 may be formed in the mesh shape in the whole area of the display apparatus.

The second trench T2 may be disposed between the first trench T1 and the first electrode 44. The second trench T2 may surround the first electrode 44 in a shape corresponding to the first electrode 44. Accordingly, a plurality of second trenches T2 may be individually arranged to surround the first electrode 44 without being connected to each other.

Compared to the aspect of FIG. 4, in the aspect of FIG. 5, the first trench T1 and the second trench T2 are disposed in the area between the sub-pixels SP1, SP2, and SP3 emitting the light of the same color. Accordingly, display quality may be improved compared to the aspect of FIG. 4.

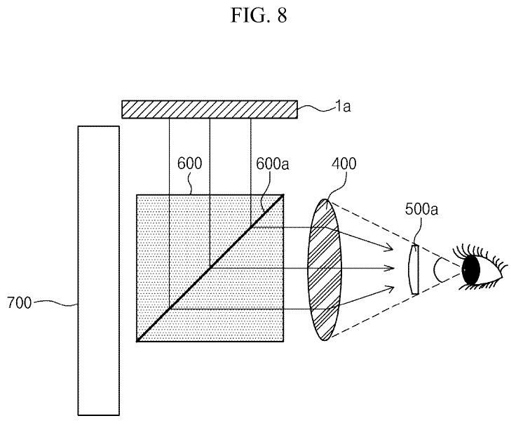

FIGS. 6 to 8 relate to the head-mounted display including the display apparatus of the present disclosure. FIG. 6 is a schematic perspective view of the head-mounted display, FIG. 7 is a schematic plan view of a virtual reality structure, and FIG. 8 is a schematic cross-sectional view of an Augmented Reality structure.

Referring to FIG. 6, the head-mounted display according to an aspect of the present disclosure includes a storage case 200 and a head-mounted band 300.

The storage case 200 stores components such as the display apparatus, a lens array, and an eyepiece lens therein.

The head mounting band 300 may be fixed to the storage case 200. The head mounting band 300 surrounds the top and both sides of the user's head, but is not limited to this. The head mounting band 300 is used to fix the head mounted display to the user's head, and may be replaced with a structure in the form of a glasses frame or a helmet.

Referring to FIG. 7, the head-mounted display with the virtual reality structure according to the present disclosure includes a left-eye display apparatus 1a, a right-eye display apparatus 1b, a lens array 400, a left eyepiece lens 500a, and a right eyepiece lens 500b.

The left-eye display apparatus 1a, the right-eye display apparatus 1b, the lens array 400, the left eyepiece lens 500a, and right eyepiece lens 500b are stored in the storage case 200.

The left-eye display apparatus 1a and the right-eye display apparatus 1b may display the same image, and in this case the user may watch a 2D image. Alternatively, the left-eye display apparatus 1a may display the left-eye image and the right-eye display apparatus 1b may display the right-eye image, and in this case the user may view a three-dimensional image. Each of the left and right-eyes display apparatus 1a may be the display apparatus 1 according to FIGS. 1 to 7.

The lens array 400 may be spaced apart from the left eyepiece lens 500a and the left-eye display apparatus 1a and may be disposed therebetween.

Further, the lens array 400 may be spaced apart from the right eyepiece lens 500b and the right-eye display apparatus 1a and may be disposed therebetween. The lens array 400 may be a micro lens array. The lens array 400 may be replaced with a pin hole array. Due to the lens array 400, the image displayed on the left-eye display apparatus 1a or the right-eye display apparatus 1b is enlarged to the user.

The user's left eye LE may be located in the left eyepiece lens 500a, and the user's right eye RE may be located in the right eyepiece lens 500b.

Referring to FIG. 8, the head-mounted display with the Augmented Reality structure according to the present disclosure includes the left-eye display apparatus 1a, the lens array 400, the left eyepiece lens 500a, a transmission reflection unit 600, and a transmission window 700. In FIG. 8, only the left inner configuration is shown for convenience, and the right inner configuration is also the same as the left inner configuration.

The left-eye display apparatus 1a, the lens array 400, the left eyepiece lens 500a, the transmission reflection unit 600, and transmission window 700 may be stored in the storage case 200 described above.

The left-eye display apparatus may be disposed on one side of the transmission reflection unit 600, for example, above the transmission reflection unit 600, so as not to block the transmission window 700. Accordingly, the left-eye display apparatus 1a may provide the image to the transmission reflection unit 600 without blocking the external background seen through the transmission window 700.

The lens array 400 may be disposed between the left eyepiece lens 500a and the transmission reflection unit 600. The transmission reflection unit 600 may be disposed between the lens array 400 and the transmission window 700. The transmission reflection unit 600 may include a reflection surface 600a that transmits part of the light and reflects another part of the light. The reflective surface 600a may be formed so that the image displayed on the left-eye display apparatus 1a propagates to the lens array 400. Accordingly, the user may see both the external background and the image displayed by the left-eye display apparatus 1a through the transparent window 15. In other words, since the user may view the overlapped real background and virtual image as one image, the augmented reality may be implemented.

The above description and the accompanying drawings are merely illustrative of the technical spirit of the present disclosure, and those of ordinary skill in the art to which the present disclosure pertains may combine configurations within a range that does not depart from the essential characteristics of the present disclosure, various modifications or variations such as separation, substitution and alteration will be possible. Therefore, the aspects disclosed in the present disclosure are not intended to limit the technical spirit of the present disclosure, but to explain, and the scope of the technical spirit of the present disclosure is not limited by these aspects.

What is claimed is:

1. A display apparatus, comprising:
a substrate including a first sub-pixel and a second sub-pixel disposed adjacent to each other;
a first electrode disposed in each of the first sub-pixel and the second sub-pixel on the substrate;
a first light emitting layer on the first electrode in the first sub-pixel and a second light emitting layer on the first electrode in the second sub-pixel;
a first trench formed between the first electrode of the first sub-pixel and the first electrode of the second sub-pixel; and
a second trench formed between the first electrode of the first sub-pixel and the first trench,
wherein the first light emitting layer and the second light emitting layer are disposed over the first trench.

2. The display apparatus of claim 1, wherein a thickness of the first light emitting layer is different from that of the second light emitting layer, and
wherein a width of the first trench varies with the thickness of the first light emitting layer and the second light emitting layer.

3. The display apparatus of claim 1, wherein the substrate further includes a third sub-pixel disposed adjacent to a side of the second sub-pixel and a third light emitting layer disposed in the third sub-pixel, and
wherein the first trench is further disposed between the third sub-pixel and the second sub-pixel.

4. The display apparatus of claim 3, wherein the width of the first trench between the first sub-pixel and the second sub-pixel is different the width of the first trench between the third sub-pixel and the second sub-pixel.

5. The display apparatus of claim 1, wherein each of the first sub-pixel and the second sub-pixel includes a plurality of sub-pixels arranged along a first direction, and
wherein the first trench is disposed along a second direction perpendicular to the first direction in areas between the plurality of first sub-pixels and between the plurality of the second sub-pixels.

6. The display apparatus of claim 5, wherein a width of the first trench disposed between the plurality of first sub-pixels is different from a width of the first trench disposed between the plurality of second sub-pixels.

7. The display apparatus of claim 1, wherein a distance from the substrate to a bottom of the first trench is greater than the distance from the substrate to a bottom of the second trench.

8. The display apparatus of claim 1, wherein the first light emitting layer is disconnected within the second trench.

9. The display apparatus of claim 1, further comprising a first insulating layer and a second insulating layer disposed over the substrate,
wherein at least one of the first trench and second trench is a removed portion of at least one of the first insulating layer and the second insulating layer.

10. The display apparatus of claim 9, further comprising a first fence disposed between the first trench and the second trench,
wherein the first fence includes a first layer made of a same material as the first electrode and a part of the second insulating layer.

11. The display apparatus of claim 10, further comprising a reflective layer disposed under the first electrode,
wherein the first fence further includes a second layer made of a same material as the reflective layer.

12. The display apparatus of claim 9, further comprising a second fence disposed between the second trenches,
wherein the second fence includes a part of end of the first electrode and a part of the second insulating layer overlapping the first electrode.

13. The display apparatus of claim 12, further comprising a reflective layer disposed under the first electrode,
wherein the second fence further includes a part of the reflective layer overlapping the first electrode.

14. The display apparatus of claim 1, further comprising a first auxiliary light emitting layer disposed on the first light emitting layer in the first sub-pixel,
wherein the first auxiliary light emitting layer emits light of a same color as the first light emitting layer.

15. The display apparatus of claim 1, wherein a color of the light emitted from the first light emitting layer is different from that of the second light emitting layer.

16. A head mount display, comprising:
a substrate including a first sub-pixel and a second sub-pixel disposed adjacent to each other;
a first electrode disposed in each of the first sub-pixel and the second sub-pixel on the substrate;
a first light emitting layer on the first electrode in the first sub-pixel and a second light emitting layer on the first electrode in the second sub-pixel;
a first trench formed between the first electrode of the first sub-pixel and the first electrode of the second sub-pixel; and
a second trench formed between the first electrode of the first sub-pixel and the first trench,
wherein the first light emitting layer and the second light emitting layer are disposed over the first trench;
a lens array space apart from the display apparatus; and
a storage case receiving the display apparatus and the lens array.
